(19) United States
(12) Patent Application Publication
(10) Pub. No.: US 2026/0360393 A1
(43) Pub. Date: Nov. 12, 2026

(54) MEMORY DEVICES AND METHODS OF MANUFACTURING THEREOF

(71) Applicant: Taiwan Semiconductor Manufacturing Company, Ltd., Hsinchu (TW)

(72) Inventors: Ayumu Yamada, Hsinchu (TW); Ryota Watanabe, Hsinchu (TW)

(73) Assignee: Taiwan Semiconductor Manufacturing Company, Ltd., Hsinchu (TW)

(21) Appl. No.: 19/199,768

(22) Filed: May 6, 2025

(51) Int. Cl. G11C 5/06; H10B 20/00

(52) U.S. Cl. CPC G11C 5/063; H10B 20/50

(57) ABSTRACT

A memory device includes a plurality of memory cells, each of the plurality of memory cells including a first transistor and a second transistor that are vertically stacked on top of each other, a word line commonly connected to respective gate terminals of the first transistor and the second transistor, a first bit line connected to a first source/drain terminal of the first transistor, and a second bit line connected to a first source/drain terminal of the second transistor. A second source/drain terminal of the first transistor and a second source/drain terminal of the second transistor are configured as being one of: (i) connected to a first power rail carrying a first supply voltage and connected to a second power rail carrying a second supply voltage, respectively, (ii) connected to the first power rail and floating, (iii) floating and connected to the second power rail, or (iv) both floating.

### BACKGROUND

The semiconductor integrated circuit (IC) industry has experienced exponential growth. As ICs continue to scale down, more devices are integrated into the single chip. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of an example memory device (or circuit), in accordance with some embodiments.

FIG. 2 illustrates a circuit diagram of an example memory circuit (or an example memory device), in accordance with some embodiments.

FIG. 3 illustrates an example layout configured to form a memory circuit, in accordance with some embodiments.

FIG. 4 illustrates an example layout configured to form a memory circuit, in accordance with some embodiments.

FIG. 5 illustrates a circuit diagram of an example memory circuit (or an example memory device), in accordance with some embodiments.

FIG. 6 illustrates example waveforms of various signals associated with a memory circuit (or an example memory device), in accordance with some embodiments.

FIG. 7 illustrates a circuit diagram of an example memory circuit (or an example memory device), in accordance with some embodiments.

FIG. 8 illustrates example waveforms of various signals associated with a memory circuit (or an example memory device), in accordance with some embodiments.

FIG. 9 illustrates a circuit diagram of an example memory circuit (or an example memory device), in accordance with some embodiments.

FIG. 10 illustrates an example layout configured to form a memory circuit, in accordance with some embodiments.

FIG. 11 illustrates an example layout configured to form a memory circuit, in accordance with some embodiments.

FIG. 12 illustrates a circuit diagram of an example memory circuit (or an example memory device), in accordance with some embodiments.

FIG. 13 illustrates a circuit diagram of an example memory circuit (or an example memory device), in accordance with some embodiments.

FIG. 14 illustrates an example layout configured to form a memory circuit, in accordance with some embodiments.

FIG. 15 illustrates an example layout configured to form a memory circuit, in accordance with some embodiments.

FIG. 16 illustrates a circuit diagram of an example memory circuit (or an example memory device), in accordance with some embodiments.

FIG. 17 illustrates a circuit diagram of an example memory circuit (or an example memory device), in accordance with some embodiments.

FIG. 18 illustrates a circuit diagram of an example memory circuit (or an example memory device), in accordance with some embodiments.

FIG. 19 illustrates a circuit diagram of an example memory circuit (or an example memory device), in accordance with some embodiments.

FIG. 20 illustrates a circuit diagram of an example memory circuit (or an example memory device), in accordance with some embodiments.

FIG. 21 illustrates example waveforms of various signals associated with a memory circuit (or an example memory device), in accordance with some embodiments.

FIG. 22 illustrates a flow chart of an example method for forming a memory circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

With the ongoing advancements in fabrication technology, stacked-transistor structures, such as Complementary FETs (CFETs), are being explored to promote the miniaturization of integrated circuits. These structures offer potential improvements in power, performance, and area (PPA) metrics. However, conventional read-only memory (ROM) circuits have been primarily designed for non-stacked transistor configurations, leading to challenges in optimizing performance when applied to stacked-transistor designs. The ROM circuit design for CFET devices typically includes a bit line (BL) shared by stacked N-type Metal-Oxide-Semiconductor (NMOS) and P-type Metal-Oxide-Semiconductor (PMOS) transistors. The source of the NMOS transistor is connected to either the bit line (or left floating) or VSS, while the PMOS source is connected to either the bit line or VDD. In this configuration, the NMOS and PMOS cells are read alternately, assuming the pre-charge level is at VDD/VSS. However, this approach is limited by the specific connection scheme and does not account for further optimizations that could increase a bit density, throughput, and operational frequency. Therefore, there is a need for an improved ROM circuit design for CFET-based stacked-transistor structures, capable of addressing these constraints and advancing the capabilities of integrated circuits.

The present disclosure provides techniques for stacked transistors. In some embodiments, the ROM circuit may include a first bit line connected to a first source/drain terminal of a first transistor, and a second bit line connected to a first source/drain terminal of a second transistor. The second source/drain terminals of the first and second transistors can be configured in various ways: (i) connected to a first power rail carrying a first supply voltage (e.g., VDD) and to a second power rail carrying a second supply voltage (e.g., VSS), respectively, (ii) connected to the first power rail and floating, (iii) floating and connected to the second power rail, or (iv) both floating. This flexible configuration enables improved bit density, operational frequency, and power efficiency, making the ROM circuit suitable for a wide range of applications. Furthermore, these offer significant improvements in the PPA metrics. Specifically, the operational frequency and throughput of the ROM circuits can be enhanced, contributing to higher overall system performance. Furthermore, both active and stand-by power consumption can be optimized, offering a reducing in power usage.

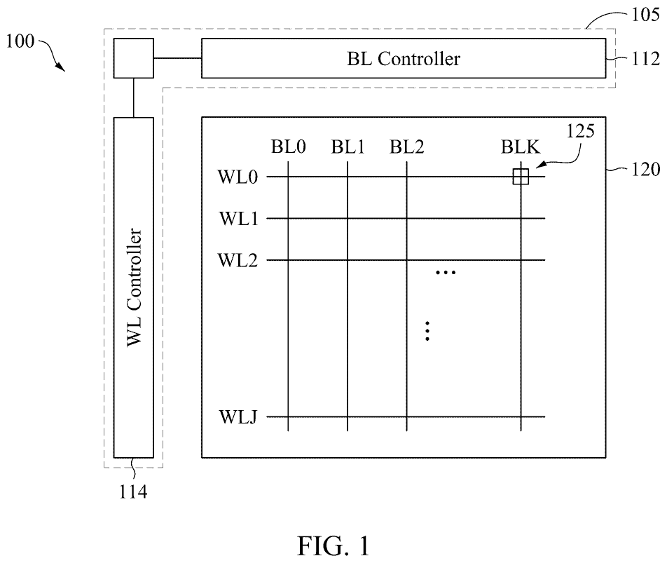

FIG. 1 illustrates a block diagram of an example memory device (or circuit) 100, in accordance with some embodiments. The memory circuit 100 includes a memory controller 105 and a memory array 120. In one aspect, the memory array 120 includes a plurality of storage circuits or memory cells 125. The memory array 120 further includes word lines WL₀, WL₁ . . . . WL_{J}, each extending in a direction (e.g., X-direction) and bit lines BL₀, BL₁ . . . . BL_{K}, each extending in another direction (e.g., Y-direction). The word lines WLs and the bit lines BLs may each be a conductive metal or conductive rail. In some embodiments, each memory cell 125 is coupled to a corresponding word line WL and a corresponding bit line BL, and can be operated according to voltages or currents through the corresponding word line WL and the corresponding bit line BL. In some embodiments, each bit line includes bit lines BL, BLB coupled to one or more memory cells 125 of a group of memory cells 125 disposed along the direction (e.g., Y-direction).

Each memory cell 125 may include a volatile memory cell, a non-volatile memory cell, or a combination of them. In some embodiments, each of the memory cells 125 may be operatively configured as a read-only-memory (ROM) cell. In some embodiments, the memory cells 125 each include a resistive random access memory (RRAM) cell. In some embodiments, each memory cell 125 is embodied as a static random access memory (SRAM) cell, etc. However, it should be appreciated that the memory cell 125 can be implemented as any of various other non-volatile memory cells such as, for example, a magnetoresistive random access memory (MRAM) cell, a phase-change random access memory (PCRAM) cell, an eFuse, an anti-fuse, etc., while remaining within the scope of the present disclosure. In some embodiments, the memory array 120 includes additional lines (e.g., select lines, reference lines, reference control lines, power rails, etc.).

The memory controller 105 is a hardware component that controls operations of the memory array 120. In some embodiments, the memory controller 105 includes a bit line (BL) controller 112, a word line (WL) controller 114, etc. The BL controller 112 and the WL controller 114 may be embodied as logic circuits, analog circuits, or a combination of them. In one configuration, the WL controller 114 can be a circuit that provides a voltage or current through one or more word lines (WLs) of the memory array 120. The BL controller 112 can be a circuit that provides or senses a voltage or current through one or more bit lines BLs of the memory array 120. The BL controller 112 may be coupled to bit lines BLs of the memory array 120, and the WL controller 114 may be coupled to word lines WLs of the memory array 120.

In some embodiments, each of the memory cells 125 may include a first transistor and a second transistor that are vertically stacked on top of each other. The word line WL may be commonly connected to respective gate terminals of the first transistor and the second transistor, while a first bit line is connected to a first source/drain terminal of the first transistor, and a second bit line is connected to a first source/drain terminal of the second transistor. In some embodiments, a second source/drain terminal of the first transistor and a second source/drain terminal of the second transistor may be configured as being one of: (i) connected to a first power rail carrying a first supply voltage and connected to a second power rail carrying a second supply voltage, respectively, (ii) connected to the first power rail and floating, (iii) floating and connected to the second power rail, or (iv) both floating.

With the foregoing in mind, the figures and description below illustrate various examples of the techniques for memory circuits (e.g., the memory circuit 100). The figures and description below are non-limiting examples and can be implemented as any of various other configurations while remaining within the scope of the present disclosure. Other embodiments can be used in addition or instead. Details that can be apparent to a person of ordinary skill in the art may be omitted. Some embodiments can be practiced with additional components or steps and/or without all of the components or steps that are described.

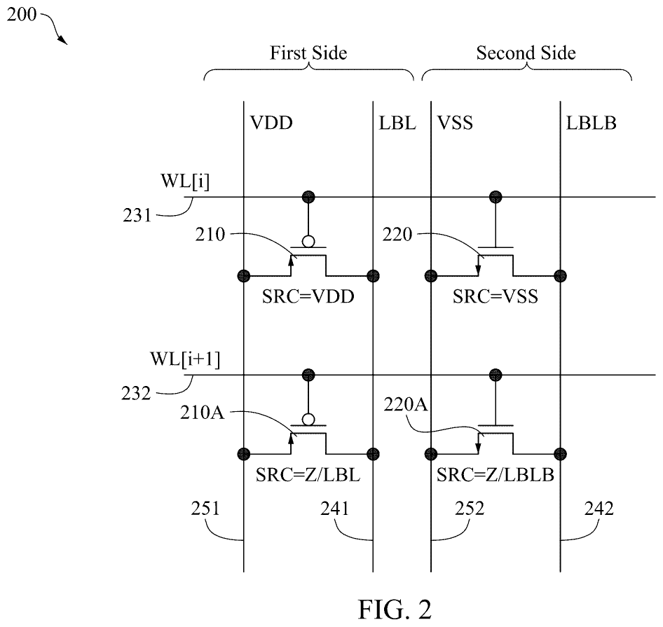

FIG. 2 illustrates a circuit diagram of an example memory circuit (or an example memory device) 200, in accordance with some embodiments. In some embodiments, the memory circuit 200 may be substantially similar to or incorporate features of the memory circuit 100. The memory circuit 200 is shown to include a first transistor 210, another first transistor 210A, a second transistor 220, another second transistor 220A, a first word line 231, a second word line 232, a first bit line 241, a second bit line 242, a first conductive rail 251, a second conductive rail 252, etc. It should be appreciated that the memory circuit 200 of FIG. 2 is simplified for illustrative purposes, and thus, can be implemented as any of various other configurations while remaining within the scope of the present disclosure.

In some embodiments, the first transistor 210 and the second transistor 220 may be vertically stacked on top of each other. In some embodiments, the first transistor 210 and the second transistor 220 may have a common conductive type. For example, each of the first transistor 210 and the second transistor 220 may have an N-type or a P-type. In some embodiments, the first transistor 210 and the second transistor 220 may have respectively different conductive types. For example, the first transistor 210 may have a P-type, and the second transistor 220 may have an N-type, or vice versa.

In some embodiments, respective gate terminals of a plurality of stacked transistors of the memory circuit 200 may be connected to a corresponding one of the word lines (e.g., the first word line 231, the second word line 232, etc.). For example, as shown, the first word line 231 may be commonly connected to respective gate terminals of the first transistor 210 and the second transistor 220. That is, the first word line 231 may be shared by the stacked transistors (e.g., the first transistor 210 and the second transistor 220).

In some embodiments, the first bit line 241 may be connected to a first source/drain terminal of the first transistor 210. The second bit line 242 may be connected to a first source/drain terminal of the second transistor 220. In some embodiments, the first bit line 241 may be a local bit line (LBL). The second bit line 242 may be a local bit line (LBLB). As shown in FIG. 2, in some embodiments, the first bit line 241 may be commonly connected to respective first source/drain terminals of a plurality of first transistors (e.g., including the first transistor 210 and the other first transistor 210A) of the memory cells. The second bit line 242 may be commonly connected to respective first source/drain terminals of a plurality of second transistors (e.g., including the second transistor 220 and the other second transistor 220A) of the memory cells.

In some embodiments, respective second source/drain terminals of the first and second transistors of each of the memory cells may be configured as being one of: (i) connected to a first supply voltage (e.g., VDD) and connected to a second supply voltage (e.g., VSS), respectively, (ii) connected to the first supply voltage and floating, (iii) floating and connected to the second supply voltage, or (iv) both floating. For example, as shown, a second source/drain terminal of the first transistor 210 and a second source/drain terminal of the second transistor 220 can be connected to the first conductive rail 251 (e.g., a first power rail carrying the first supply voltage) and the second conductive rail 252 (e.g., a second power rail carrying the second supply voltage), respectively. A second source/drain terminal of the other first transistor 210A and a second source/drain terminal of the other second transistor 220A can be both floating. Although not shown, in some embodiments, the second source/drain terminal of the first transistor 210 and the second source/drain terminal of the second transistor 220 can be (ii) connected to the first power rail carrying the first supply voltage and floating, or (iii) floating and connected to the second power rail carrying the second supply voltage. The configuration and arrangement (e.g., of the first transistor 210, the second transistor 220, etc.) discussed herein are non-limiting examples and can be implemented as any of various other configurations while remaining within the scope of the present disclosure. In some examples, although not shown in FIG. 2, the memory circuit 200 may include a memory cell including stacked transistors (e.g., the first transistor 210 and the second transistor 220), while including another memory cell including one or more non-stacked transistors. In some implementations, each transistor of each cell (e.g., the first transistor 210, the second transistor 220) may be connected to a bit line (e.g., the first bit line 241, the second bit line 242, etc.), connected to a supply voltage (e.g., the first conductive rail 251, the second conductive rail 252, etc.), or floating, in various manners. For example, as shown in Table 1 below, each of a first source/drain (S/D) terminal and a second S/D terminal of the transistor may be configured as being one of: connected to the bit line (e.g., the first bit line 241, the second bit line 242, etc.), connected to the supply voltage (e.g., the first conductive rail 251, the second conductive rail 252, etc.), and floating.

TABLE 1

| # | 1st S/D terminal | 2nd S/D terminal | Cell state |
|---|---|---|---|
| A | Supply voltage | Supply voltage | Off |
| B | Supply voltage | Floating | Off |
| C | Supply voltage | Bit line | On |
| D | Floating | Supply voltage | Off |
| E | Floating | Floating | Off |
| F | Floating | Bit line | Off |
| G | Bit line | Supply voltage | On |
| H | Bit line | Floating | Off |
| I | Bit line | Bit line | Off |

For example, with first S/D terminal connected to the supply voltage and the second S/D terminal connected to supply voltage (“A”), the cell may be placed in an “Off” state. With first S/D terminal connected to the supply voltage and the second S/D terminal floating (“B”), the cell may be placed in an “Off” state. With first S/D terminal connected to the supply voltage and the second S/D terminal connected to the bit line (“C”), the cell may be placed in an “On” state. With first S/D terminal floating and the second S/D terminal connected to the supply voltage (“D”), the cell may be placed in an “Off” state. With first S/D terminal floating and the second S/D terminal floating (“E”), the cell may be placed in an “Off” state. With first S/D terminal floating and the second S/D terminal connected to the bit line (“F”), the cell may be placed in an “Off” state. With first S/D terminal connected to the bit line and the second S/D terminal connected to the supply voltage (“G”), the cell may be placed in an “On” state. With first S/D terminal connected to the bit line and the second S/D terminal floating (“H”), the cell may be placed in an “Off” state. With first S/D terminal connected to the bit line and the second S/D terminal connected to the bit line (“I”), the cell may be placed in an “Off” state.

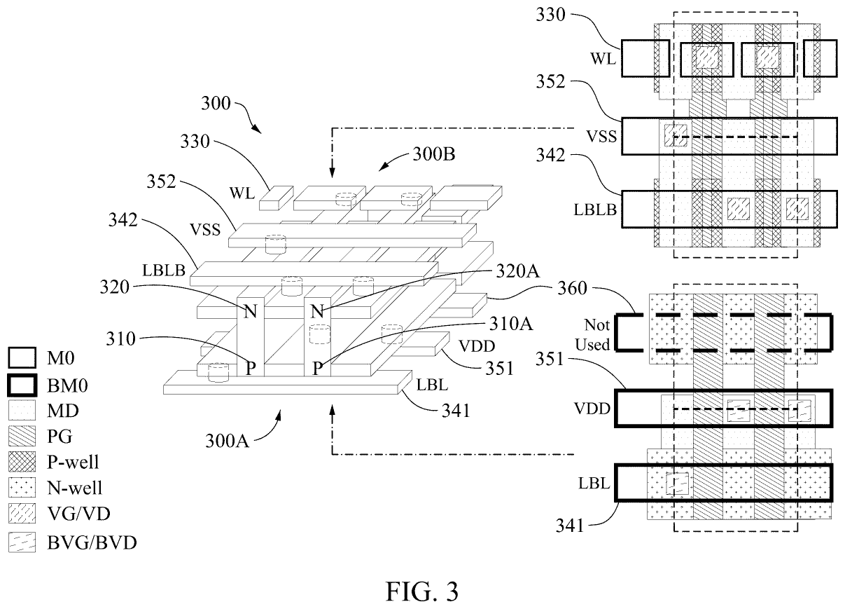

FIG. 3 illustrates an example layout 300 configured to form a memory circuit, in accordance with some embodiments. In some embodiments, the layout 300 may be configured to form the memory circuits 100, 200, etc. In FIG. 3, top views of a first side 300A (e.g., a bottom) and a second side 300B (e.g., a top) of the layout 300 are shown. It should be appreciated that the layout 300 of FIG. 3 is simplified for illustrative purposes, and thus, can be implemented as any of various other configurations while remaining within the scope of the present disclosure.

The layout 300 is shown to include a first transistor 310, another first transistor 310A, a second transistor 320, another second transistor 320A, a first metal track 341, a second metal track 351, a third metal track 342, a fourth metal track 352, and a fifth metal track 330. These components of the layout 300 may be associated with the first transistor 210, the other first transistor 210A, the second transistor 220, the other second transistor 220A, the first word line 231, the first bit line 241, the first conductive rail 251, the second bit line 242, the second conductive rail 252, and the word line (e.g., the first word line 231, the second word line 232, etc.), respectively, shown in FIG. 2.

In some embodiments, the first bit line (e.g., the first bit line 241 of FIG. 2) and the first power rail (e.g., the first conductive rail 251 of FIG. 2) may be formed as the first metal track 341 and the second metal track 351, respectively. In some embodiments, the second bit line (e.g., the second bit line 242 of FIG. 2), the second power rail (e.g., the second conductive rail 252 of FIG. 2), and the word line (e.g., the first word line 231, the second word line 232, etc. of FIG. 2) may be formed as the third metal track 342, the fourth metal track 352, and the fifth metal track 330, respectively. In some embodiments, the first metal track 341 and the second metal track 351 may be formed below the stacked transistors (e.g., the first transistor 310 and the second transistor 320, etc.), while the third metal track 342, the fourth metal track 352, and the fifth metal track 330 may be formed above the stacked transistors (e.g., the first transistor 310 and the second transistor 320, etc.). For example, as shown in FIG. 3, the first metal track 341 and the second metal track 351 may be formed on a first metallization layer BM0, which may be located below the stacked transistors. The third metal track 342, the fourth metal track 352, and the fifth metal track 330 may be formed on a second metallization layer MO, which may be located above the stacked transistors.

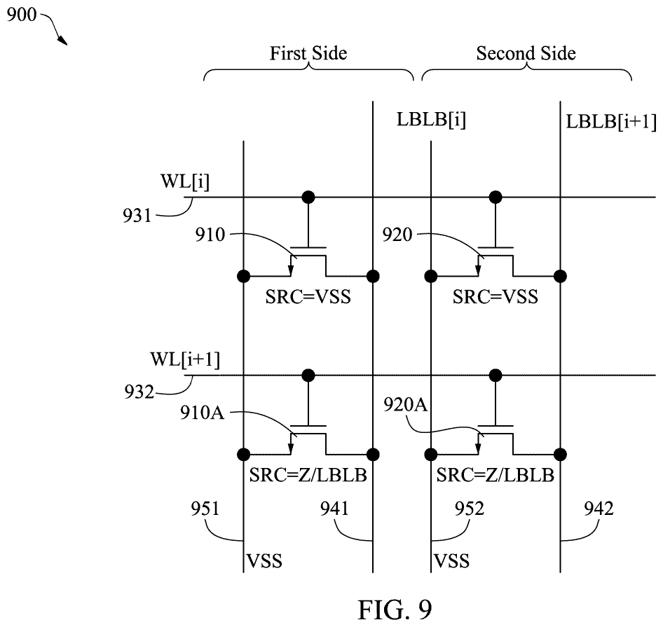

In some embodiments, the first transistor 310 and the second transistor 320 may have a common conductive type. For example, each of the first transistor 310 and the second transistor 320 may have an N-type or a P-type. In some embodiments, the first transistor 310 and the second transistor 320 may have respectively different conductive types. For example, as shown in FIG. 3, the first transistor 310 may have a P-type, and the second transistor 320 may have an N-type, or vice versa. The conductive types of the first transistor 310 and the second transistor 320 are not limited to those shown in FIGS. 2 and 3. For example, as shown in FIGS. 9 to 15, the conductive types of the first transistor 310 and the second transistor 320 may vary without departing from the spirit and scope of the present disclosure.

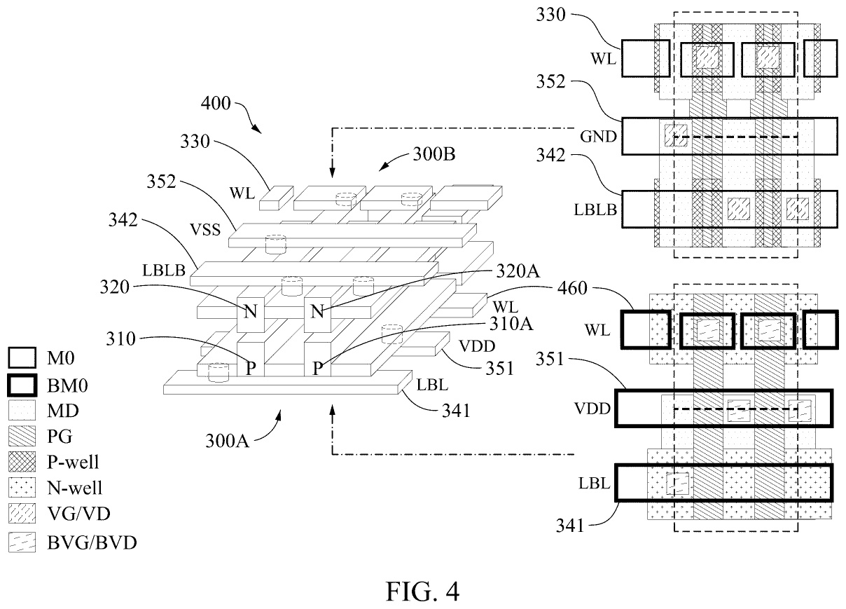

In some embodiments, the first metallization layer BM0 may include a portion 360 that is not used (“Not Used”). For example, the portion 360 may be a metal track that is not connected to the stacked transistors. The portion 360, as discussed below and shown in FIG. 4, may be configured as a portion of a word line.

FIG. 4 illustrates an example layout 400 configured to form a memory circuit, in accordance with some embodiments. In some embodiments, the layout 400 may be configured to form the memory circuits 100, 200, etc. In FIG. 4, top views of a first side 400A (e.g., a bottom) and a second side 400B (e.g., a top) of the layout 400 are shown. It should be appreciated that the layout 400 of FIG. 4 is simplified for illustrative purposes, and thus, can be implemented as any of various other configurations while remaining within the scope of the present disclosure.

In some embodiments, the layout 400 may be substantially similar to or incorporate features of the layout 300 of FIG. 3. For example, the layout 400 may be the layout 300 that alternatively includes a sixth metal track 460, as opposed to the portion 360. In some embodiments, the layout 400 may include the first transistor 310 and the second transistor 320 that are vertically arranged (e.g., as shown in FIG. 4) without being in contact with each other.

In some embodiments, a portion of the word line may be formed as the sixth metal track 460. For example, the portions of the first word line (e.g., the first word line 231, the second word line 232, etc.) that are associated with the first transistor 310 and the other first transistor 310A may be formed as the sixth metal track 460. In some embodiments, the sixth metal track 460 may be formed below the stacked transistors (e.g., the first transistor 310, the second transistor 320, etc.).

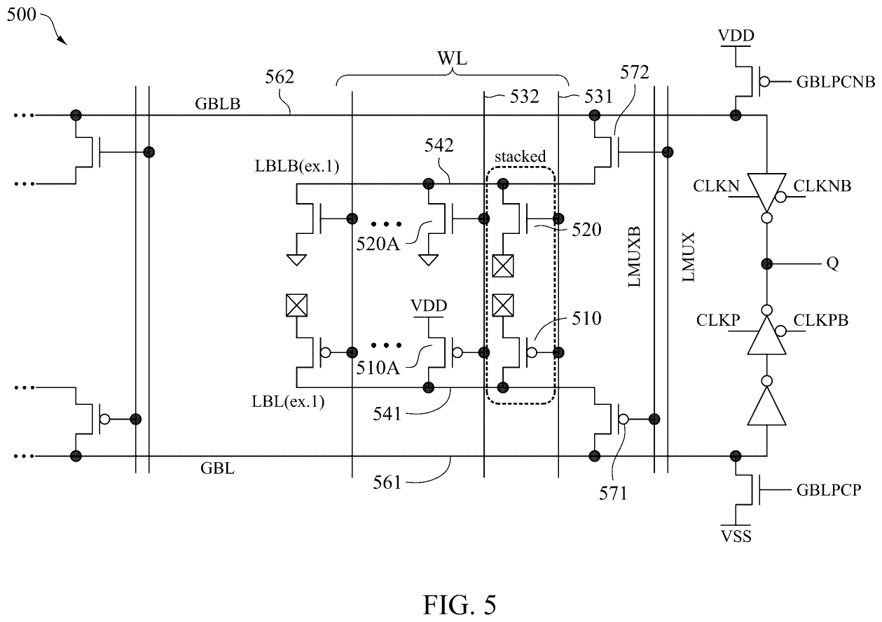

FIG. 5 illustrates a circuit diagram of an example memory circuit (or an example memory device) 500, in accordance with some embodiments. In some embodiments, the memory circuit 500 may be substantially similar to or incorporate features of the memory circuit 100, the memory circuit 200, etc. For example, the memory circuit 500 includes a first transistor 510, another first transistor 510A, a second transistor 520, another second transistor 520A, a first word line 531, a second word line 532, a first bit line 541, and a second bit line 542, etc. The memory circuit 500 may include a first global bit line 561, a second global bit line 562, a first bit line transistor 571, and a second bit line transistor 572 additionally, as opposed to the memory circuit 200. It should be appreciated that the memory circuit 500 of FIG. 5 is simplified for illustrative purposes, and thus, can be implemented as any of various other configurations while remaining within the scope of the present disclosure.

The first transistor 510 and the second transistor 520 may be vertically stacked on top of each other. In some embodiments, the first transistor 510 and the second transistor 520 may have a common conductive type. For example, each of the first transistor 510 and the second transistor 520 may have an N-type or a P-type. In some embodiments, the first transistor 510 and the second transistor 520 may have respectively different conductive types. For example, the first transistor 510 may have a P-type, and the second transistor 520 may have an N-type, or vice versa.

In some embodiments, respective gate terminals of a plurality of stacked transistors of the memory circuit 500 may be connected to a corresponding one of the word lines (e.g., the first word line 531, the second word line 532, etc.). For example, as shown, the first word line 531 may be commonly connected to respective gate terminals of the first transistor 510 and the second transistor 520. In some embodiments, the first bit line 541 may be connected to a first source/drain terminal of the first transistor 510. The second bit line 542 may be connected to a first source/drain terminal of the second transistor 520. In some embodiments, the first bit line 541 may be a local bit line (LBL). The second bit line 542 may be a local bit line (LBLB). As shown in FIG. 5, in some embodiments, the first bit line 541 may be commonly connected to respective first source/drain terminals of a plurality of first transistors (e.g., including the first transistor 510 and the other first transistor 510A) of the memory cells. The second bit line 542 may be commonly connected to respective first source/drain terminals of a plurality of second transistors (e.g., including the second transistor 520 and the other second transistor 520A) of the memory cells.

In some embodiments, the first global bit line 561 may be connected to the first bit line 541. The second global bit line 562 may be connected to the second bit line 542. In some embodiments, the first global bit line 561 may be connected to the first bit line 541 through the first bit line transistor 571. As shown in FIG. 5, a first source/drain terminal of the first bit line transistor 571 may be connected to the first bit line 541, and a second source/drain terminal of the first bit line transistor 571 may be connected to the first global bit line 561. A gate terminal of the first bit line transistor 571 can be connected to a line assertion signal LMUXB. In some embodiments, the second global bit line 562 may be connected to the second bit line 542 through the second bit line transistor 572. As shown in FIG. 5, a first source/drain terminal of the second bit line transistor 572 may be connected to the second bit line 542, and a second source/drain terminal of the second bit line transistor 572 may be connected to the second global bit line 562. A gate terminal of the second bit line transistor 572 can be connected to a line assertion signal LMUX.

In some embodiments, the first bit line transistor 571 and the second bit line transistor 572 may have a common conductive type. For example, each of the first bit line transistor 571 and the second bit line transistor 572 may have an N-type or a P-type. In some embodiments, the first bit line transistor 571 and the second bit line transistor 572 may have respectively different conductive types. For example, the first bit line transistor 571 may have a P-type, and the second bit line transistor 572 may have an N-type, or vice versa.

The configuration and arrangement (e.g., of the first transistor 510, the second transistor 520, the first global bit line 561, the second global bit line 562, etc.) discussed herein are non-limiting examples and can be implemented as any of various other configurations while remaining within the scope of the present disclosure. For example, although not shown in FIG. 5, the memory circuit 500 may include a plurality of global bit lines (e.g., the first global bit line 561, the second global bit line 562, etc.), each of which is connected to one or more sets of local bit lines (e.g., the first bit line 541, the second bit line 542, etc.). In some embodiments, although not shown, the memory circuit 500 may include a conductive rail (e.g., the first conductive rail 251, the second conductive rail 252, etc.), while including the first global bit line 561 and the second global bit line 562.

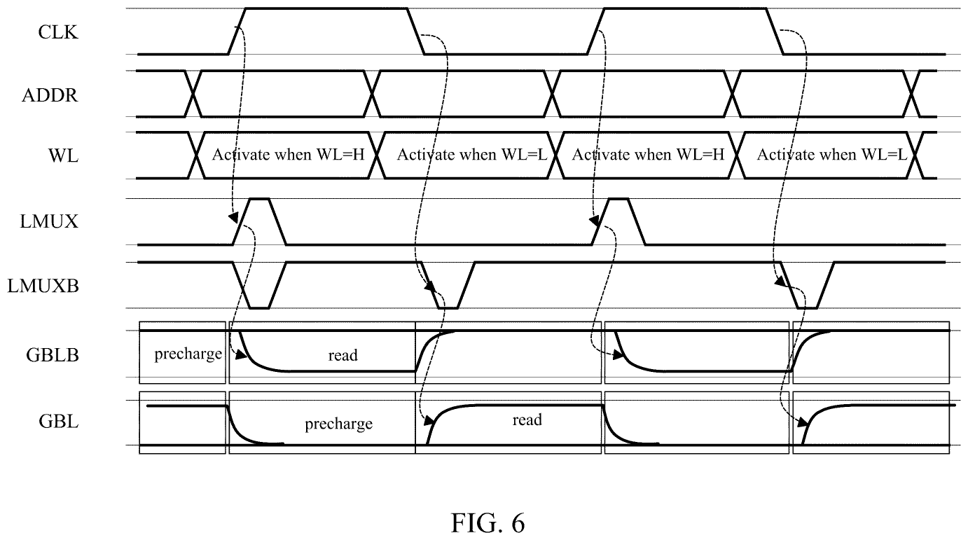

FIG. 6 illustrates example waveforms of various signals associated with a memory circuit (or an example memory device), in accordance with some embodiments. For example, a clock signal (CLK), an address signal (ADDR), a word line assertion signal WL, a line assertion signal LMUX, a line assertion signal LMUXB, a global bit line signal GBL, a global bit line signal GBLB, etc. are shown. It should be appreciated that the waveforms of FIG. 6 are simplified for illustrative purposes.

Prior to activation of the word line assertion signal WL, the global bit line signal GBL (or GBLB) can be pre-charged to a supply voltage VDD (or VSS). Based on the clock signal CLK, the line assertion signal LMUX (or LMUXB) can be provided as a pulse. The selected cell data (e.g., in an NMOS cell, a PMOS cell, etc.) can be thereby read as a voltage of the global bit line signal GBL (or GBLB), based on the line assertion signal LMUX (or LMUXB). This enables each of the memory cells (e.g., NMOS and PMOS cells) to perform a read operation alternately, thereby increasing a throughput, for example, by a factor of 2. Thus, this can improve a bit density of the memory circuit by a factor of 2, while improving operational frequency and power efficiency.

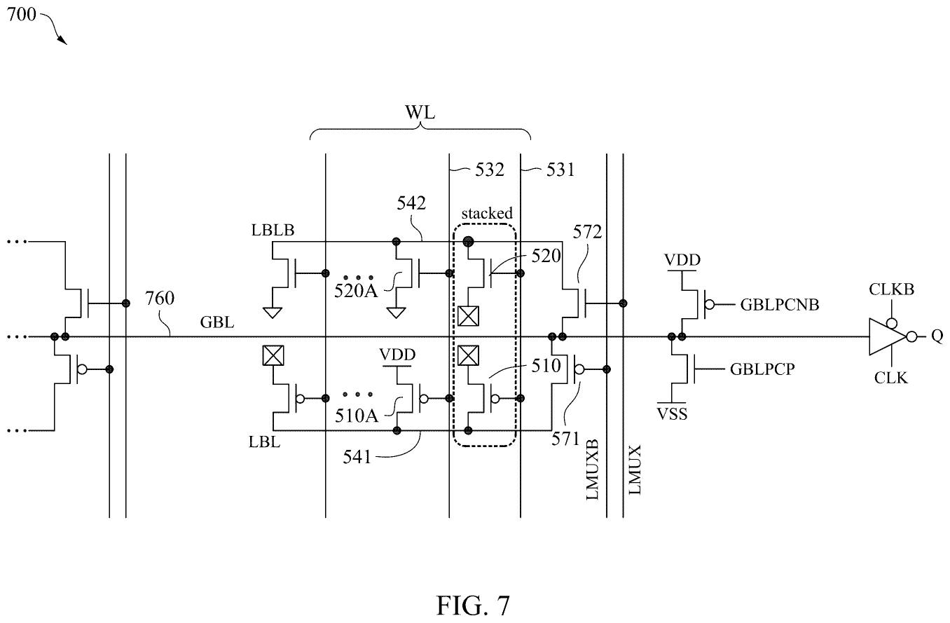

FIG. 7 illustrates a circuit diagram of an example memory circuit (or an example memory device) 700, in accordance with some embodiments. In some embodiments, the memory circuit 700 may be substantially similar to or incorporate features of the memory circuit 100, the memory circuit 200, the memory circuit 500, etc. For example, the memory circuit 700 may include a global bit line 760, as opposed to the memory circuit 500 including the first global bit line 561 and the second global bit line 562. It should be appreciated that the memory circuit 700 of FIG. 7 is simplified for illustrative purposes, and thus, can be implemented as any of various other configurations while remaining within the scope of the present disclosure.

In some embodiments, the global bit line 760 may be connected to the first bit line 541. The global bit line 760 may be connected to the second bit line 542. In some embodiments, the global bit line 760 may be connected to the first bit line 541 through the first bit line transistor 571. As shown in FIG. 7, the first source/drain terminal of the first bit line transistor 571 may be connected to the first bit line 541, and the second source/drain terminal of the first bit line transistor 571 may be connected to the global bit line 760. The gate terminal of the first bit line transistor 571 can be connected to the line assertion signal LMUXB. In some embodiments, the global bit line 760 may be connected to the second bit line 542 through the second bit line transistor 572. As shown in FIG. 7, the first source/drain terminal of the second bit line transistor 572 may be connected to the second bit line 542, and the second source/drain terminal of the second bit line transistor 572 may be connected to the global bit line 760. The gate terminal of the second bit line transistor 572 can be connected to the line assertion signal LMUX.

The configuration and arrangement (e.g., of the first transistor 510, the second transistor 520, the first global bit line 561, the second global bit line 562, etc.) discussed herein are non-limiting examples and can be implemented as any of various other configurations while remaining within the scope of the present disclosure. For example, although not shown in FIG. 7, the memory circuit 700 may include a plurality of global bit lines (e.g., global bit line 760, etc.), each of which is connected to one or more sets of local bit lines (e.g., the first bit line 541, the second bit line 542, etc.). In some embodiments, although not shown, the memory circuit 700 may include a conductive rail (e.g., the first conductive rail 251, the second conductive rail 252, etc.), while including the global bit line 760.

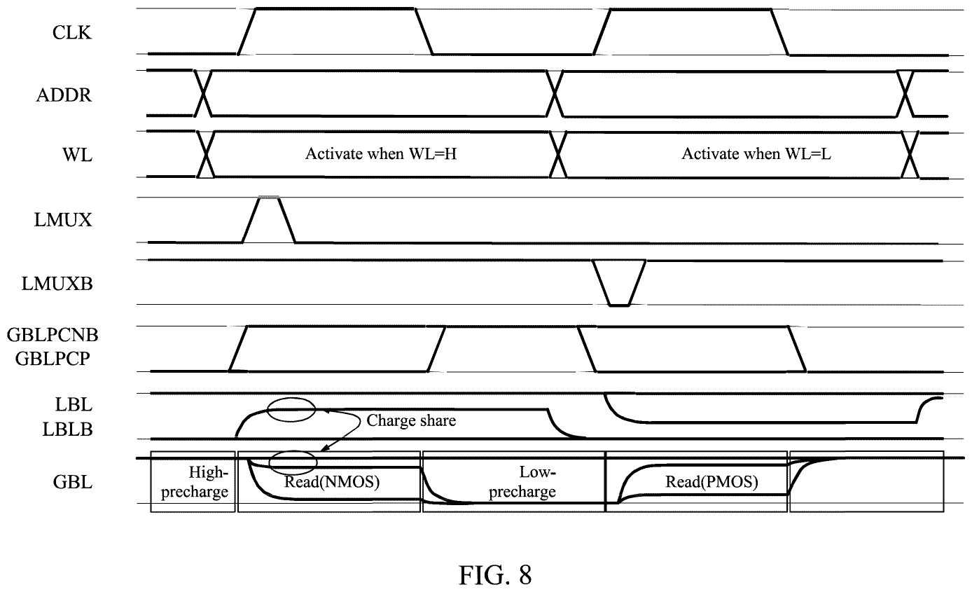

FIG. 8 illustrates example waveforms of various signals associated with a memory circuit (or an example memory device), in accordance with some embodiments. For example, a clock signal (CLK), an address signal (ADDR), a word line assertion signal WL, a line assertion signal LMUX, a line assertion signal LMUXB, a global pre-charge signal GBLPCNB, a global pre-charge signal GBLPCP, a bit line signal LBL, a bit line signal LBLB, global bit line signal GBL, etc. are shown. It should be appreciated that the waveforms of FIG. 8 are simplified for illustrative purposes.

Prior to activation of the word line assertion signal WL for an NMOS cell, the global bit line signal GBL can be pre-charged to a supply voltage VDD upon selection. Based on the clock signal CLK, the line assertion signal LMUX can be provided as a pulse. The selected cell data in the NMOS cell can be thereby read as a voltage of the global bit line signal GBL, based on the line assertion signal LMUX. Here, the bit line signal LBL and the global bit line signal GBL can share the charge with each other during the read operation of the NMOS cell. Prior to activation of the word line assertion signal WL for a PMOS cell, the global bit line signal GBL can be pre-charged to a supply voltage VSS upon selection, with a pre-charged level lower than the level for the NMOS cell. Based on the clock signal CLK, the line assertion signal LMUXB can be provided as a pulse. The selected cell data in the PMOS cell can be thereby read as a voltage of the global bit line signal GBL, based on the line assertion signal LMUXB. This enables each of the NMOS and PMOS cells to perform a read operation alternately, thereby increasing a throughput, for example, by a factor of 2. Thus, this can improve a bit density of the memory circuit by a factor of 2, while improving operational frequency and power efficiency.

The memory circuits described herein can be configured with various components and/or implementations. For example, the stacked transistors (e.g., the first transistor 210, the second transistor 220, etc. of FIG. 2) may have different conductive types. The stacked transistors may be connected to various conductive rails (e.g., the first conductive rail 251, the second conductive rail 252, etc. of FIG. 2) or be floating. The figures and description below illustrate non-limiting examples of the memory circuits with various configurations and/or implementations.

FIG. 9 illustrates a circuit diagram of an example memory circuit (or an example memory device) 900, in accordance with some embodiments. In some embodiments, the memory circuit 900 may be substantially similar to or incorporate features of the memory circuit 100, the memory circuit 200, etc. For example, the memory circuit 900 includes a first transistor 910, another first transistor 910A, a second transistor 920, another second transistor 920A, a first word line 931, a second word line 932, a first bit line 941, a second bit line 942, a first conductive rail 951, a second conductive rail 952, etc. It should be appreciated that the memory circuit 900 of FIG. 9 is simplified for illustrative purposes, and thus, can be implemented as any of various other configurations while remaining within the scope of the present disclosure

In some embodiments, respective gate terminals of a plurality of stacked transistors of the memory circuit 900 may be connected to a corresponding one of the word lines (e.g., the first word line 931, the second word line 932, etc.). For example, as shown, the first word line 931 may be commonly connected to respective gate terminals of the first transistor 910 and the second transistor 920. That is, the first word line 931 may be shared by the stacked transistors (e.g., the first transistor 910 and the second transistor 920). Although two stacked transistors (e.g., the first transistor 910 and the second transistor 920) are shown, the memory circuit 900 may include any number of transistors that are vertically stacked on top of each other. For example, the memory circuit 900 may include N transistors (e.g., N NMOS cells; wherein N=1, 2, 3, 4, 5, etc.), which can improve the bit density by a factor of N.

The N transistors may have different varieties of conductive types. For example, at least two of the N transistors (e.g., the first transistor 910 and the second transistor 920) may have a common conductive type, for example, N-type, as shown in FIG. 9. In some embodiments, at least two of the N transistors may have respectively different conductive types (not shown in FIG. 9).

In some embodiments, the first bit line 941 may be connected to a first source/drain terminal of the first transistor 910. The second bit line 942 may be connected to a first source/drain terminal of the second transistor 920. In some embodiments, the first bit line 941 may be the i-th local bit line (LBLB [i]). The second bit line 942 may be the i+1-th local bit line (LBLB [i+1]). As shown in FIG. 9, in some embodiments, the first bit line 941 may be commonly connected to respective first source/drain terminals of a plurality of first transistors (e.g., including the first transistor 910 and the other first transistor 910A) of the memory cells. The second bit line 942 may be commonly connected to respective first source/drain terminals of a plurality of second transistors (e.g., including the second transistor 920 and the other second transistor 920A) of the memory cells.

In some embodiments, respective second source/drain terminals of the first and second transistors of each of the memory cells may be configured as being one of: (i) connected to a first supply voltage (e.g., VDD) and connected to a second supply voltage (e.g., VSS), respectively, (ii) connected to the first supply voltage and floating, (iii) floating and connected to the second supply voltage, or (iv) both floating. For example, as shown, a second source/drain terminal of the first transistor 910 and a second source/drain terminal of the second transistor 920 can be connected to the first conductive rail 951 (e.g., a first power rail carrying the second supply voltage, VSS) and the second conductive rail 952 (e.g., a second power rail carrying the second supply voltage, VSS), respectively. As shown in FIG. 9, a second source/drain terminal of the other first transistor 910A and a second source/drain terminal of the other second transistor 920A can be both floating. Although not shown, in some embodiments, the second source/drain terminal of the first transistor 910 and the second source/drain terminal of the second transistor 920 can be (ii) connected to the first power rail carrying the first supply voltage and floating, or (iii) floating and connected to the second power rail carrying the second supply voltage. The configuration and arrangement (e.g., of the first transistor 910, the second transistor 920, etc.) discussed herein are non-limiting examples and can be implemented as any of various other configurations while remaining within the scope of the present disclosure. For example, although not shown in FIG. 9, the memory circuit 900 may include a memory cell including stacked transistors (e.g., the first transistor 910 and the second transistor 920), while including another memory cell including one or more non-stacked transistors.

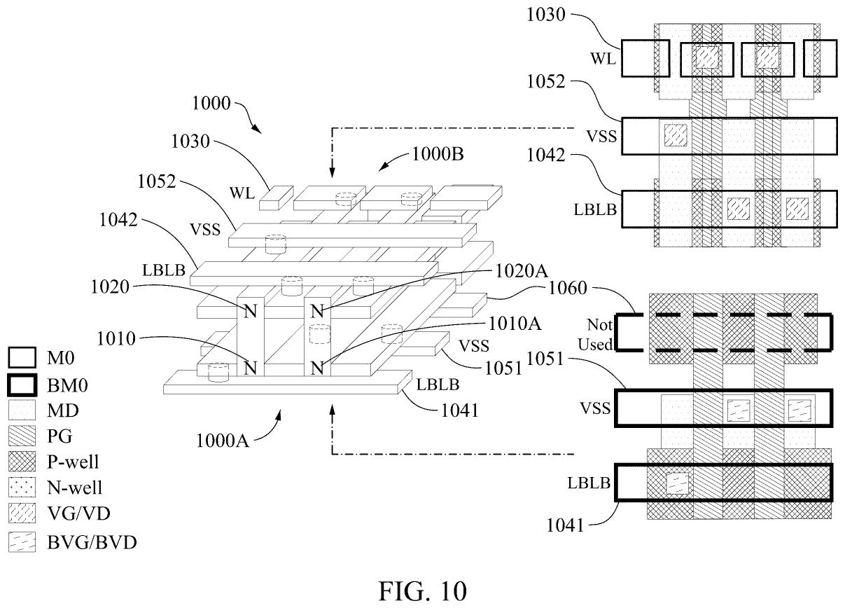

FIG. 10 illustrates an example layout 1000 configured to form a memory circuit, in accordance with some embodiments. In some embodiments, the layout 1000 may be configured to form the memory circuit 900, etc. In FIG. 10, top views of a first side 1000A (e.g., a bottom) and a second side 1000B (e.g., a top) of the layout 1000 are shown. It should be appreciated that the layout 1000 of FIG. 10 is simplified for illustrative purposes, and thus, can be implemented as any of various other configurations while remaining within the scope of the present disclosure.

The layout 1000 is shown to include a first transistor 1010, another first transistor 1010A, a second transistor 1020, another second transistor 1020A, a first metal track 1041, a second metal track 1051, a third metal track 1042, a fourth metal track 1052, and a fifth metal track 1030. These components of the layout 1000 may be associated with the first transistor 910, the other first transistor 910A, the second transistor 920, the other second transistor 920A, the first word line 931, the first bit line 941, the first conductive rail 951, the second bit line 942, the second conductive rail 952, and the word line (e.g., the first word line 931, the second word line 932, etc.), respectively, shown in FIG. 9.

In some embodiments, the first bit line (e.g., the first bit line 941 of FIG. 9) and the first power rail (e.g., the first conductive rail 951 of FIG. 9) may be formed as the first metal track 1041 and the second metal track 1051, respectively. In some embodiments, the second bit line (e.g., the second bit line 942 of FIG. 9), the second power rail (e.g., the second conductive rail 952 of FIG. 9), and the word line (e.g., the first word line 931, the second word line 932, etc. of FIG. 9) may be formed as the third metal track 1042, the fourth metal track 1052, and the fifth metal track 1030, respectively. In some embodiments, the first metal track 1041 and the second metal track 1051 may be formed below the stacked transistors (e.g., the first transistor 1010 and the second transistor 1020, etc.), while the third metal track 1042, the fourth metal track 1052, and the fifth metal track 1030 may be formed above the stacked transistors (e.g., the first transistor 1010 and the second transistor 1020, etc.). For example, as shown in FIG. 10, the first metal track 1041 and the second metal track 1051 may be formed on a first metallization layer BM0, which may be located below the stacked transistors. The third metal track 1042, the fourth metal track 1052, and the fifth metal track 1030 may be formed on a second metallization layer MO, which may be located above the stacked transistors.

In some embodiments, the first transistor 1010 and the second transistor 1020 may have a common conductive type. For example, each of the first transistor 1010 and the second transistor 1020 may have an N-type, as shown. In some embodiments, the first transistor 1010 and the second transistor 1020 may have respectively different conductive types (e.g., as shown in FIGS. 2 and 3).

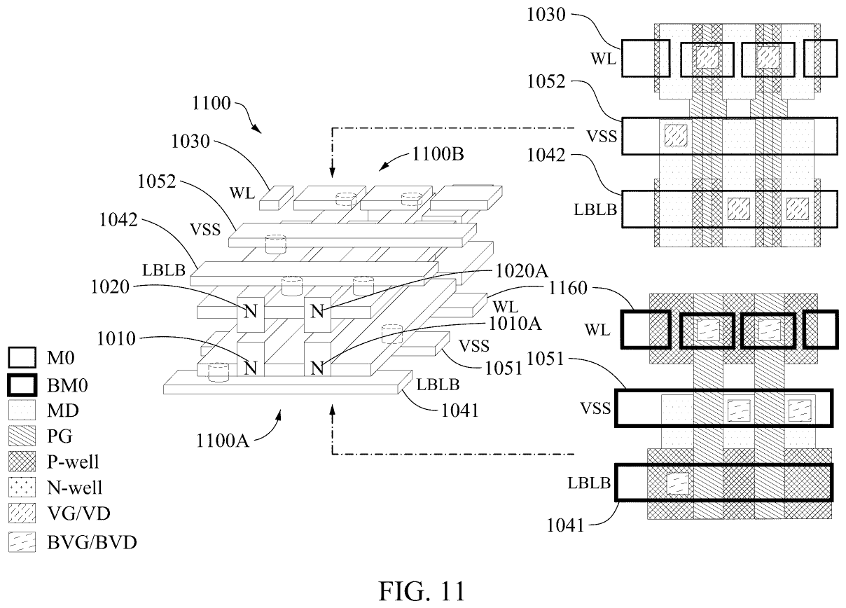

In some embodiments, the first metallization layer BM0 may include a portion 1060 that is not used (“Not Used”). For example, the portion 1060 may be a metal track that is not connected to the stacked transistors. The portion 1060, as discussed below and shown in FIG. 11, may be configured as a portion of a word line.

FIG. 11 illustrates an example layout 1100 configured to form a memory circuit, in accordance with some embodiments. In some embodiments, the layout 1100 may be configured to form the memory circuit 900, etc. In FIG. 11, top views of a first side 1100A (e.g., a bottom) and a second side 1100B (e.g., a top) of the layout 1100 are shown. It should be appreciated that the layout 1100 of FIG. 11 is simplified for illustrative purposes, and thus, can be implemented as any of various other configurations while remaining within the scope of the present disclosure.

In some embodiments, the layout 1100 may be substantially similar to or incorporate features of the layout 1000 of FIG. 10. For example, the layout 1100 may be the layout 1000 that alternatively includes a sixth metal track 1160, as opposed to the portion 1060. In some embodiments, the layout 1100 may include the first transistor 1010 and the second transistor 1020 that are vertically arranged (e.g., as shown in FIG. 11) without being in contact with each other.

In some embodiments, a portion of the word line may be formed as the sixth metal track 1160. For example, the portions of the first word line (e.g., the first word line 931, the second word line 932, etc.) that are associated with the first transistor 1010 and the other first transistor 1010A may be formed as the sixth metal track 1160. In some embodiments, the sixth metal track 1160 may be formed below the stacked transistors (e.g., the first transistor 1010, the second transistor 1020, etc.).

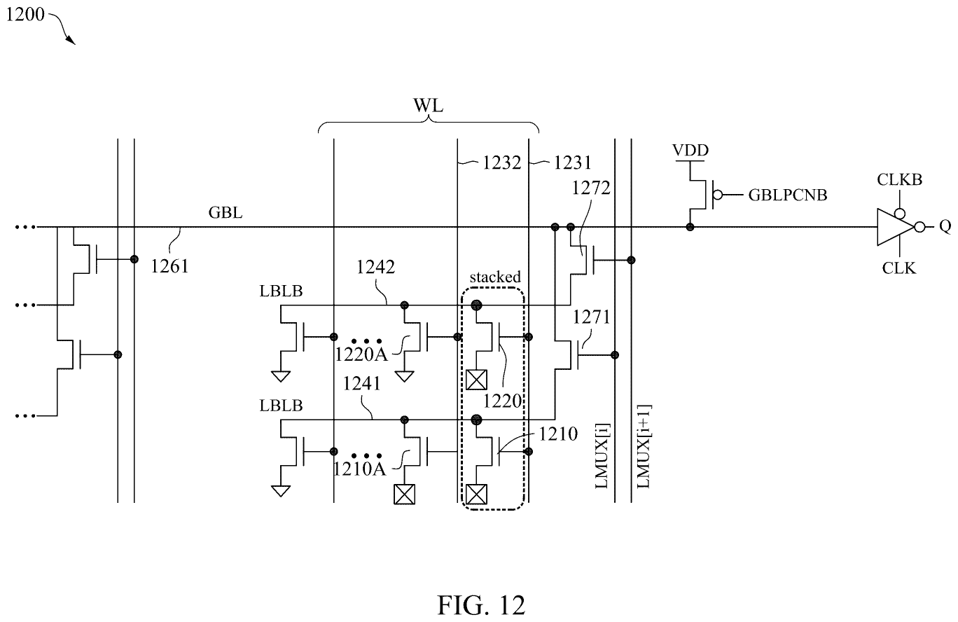

FIG. 12 illustrates a circuit diagram of an example memory circuit (or an example memory device) 1200, in accordance with some embodiments. In some embodiments, the memory circuit 1200 may be substantially similar to or incorporate features of the memory circuit 100, the memory circuit 200, the memory circuit 900, etc. For example, the memory circuit 1200 includes a first transistor 1210, another first transistor 1210A, a second transistor 1220, another second transistor 1220A, a first word line 1231, a second word line 1232, a first bit line 1241, and a second bit line 1242, etc. The memory circuit 1200 may include a global bit line 1261, a first bit line transistor 1271, and a second bit line transistor 1272 additionally, as opposed to the memory circuit 900. It should be appreciated that the memory circuit 1200 of FIG. 12 is simplified for illustrative purposes, and thus, can be implemented as any of various other configurations while remaining within the scope of the present disclosure.

In some embodiments, respective gate terminals of a plurality of stacked transistors of the memory circuit 1200 may be connected to a corresponding one of the word lines (e.g., the first word line 1231, the second word line 1232, etc.). For example, as shown, the first word line 1231 may be commonly connected to respective gate terminals of the first transistor 1210 and the second transistor 1220. In some embodiments, the first bit line 1241 may be connected to a first source/drain terminal of the first transistor 1210. The second bit line 1242 may be connected to a first source/drain terminal of the second transistor 1220. In some embodiments, the first bit line 1241 may be a first local bit line (LBLB). The second bit line 1242 may be a second local bit line (LBLB). As shown in FIG. 12, in some embodiments, the first bit line 1241 may be commonly connected to respective first source/drain terminals of a plurality of first transistors (e.g., including the first transistor 1210 and the other first transistor 1210A) of the memory cells. The second bit line 1242 may be commonly connected to respective first source/drain terminals of a plurality of second transistors (e.g., including the second transistor 1220 and the other second transistor 1220A) of the memory cells.

In some embodiments, the global bit line 1261 may be connected to the first bit line 1241 and the second bit line 1242. In some embodiments, the global bit line 1261 may be connected to the first bit line 1241 through the first bit line transistor 1271, and connected to the second bit line 1242 through the second bit line transistor 1272. As shown in FIG. 12, a first source/drain terminal of the first bit line transistor 1271 may be connected to the first bit line 1241, and a second source/drain terminal of the first bit line transistor 1271 may be connected to the global bit line 1261. A gate terminal of the first bit line transistor 1271 can be connected to an i-th line assertion signal LMUXB [i]. A first source/drain terminal of the second bit line transistor 1272 may be connected to the second bit line 1242, and a second source/drain terminal of the second bit line transistor 1272 may be connected to the global bit line 1261. A gate terminal of the second bit line transistor 1272 can be connected to an i+1-th line assertion signal LMUXB [i+1].

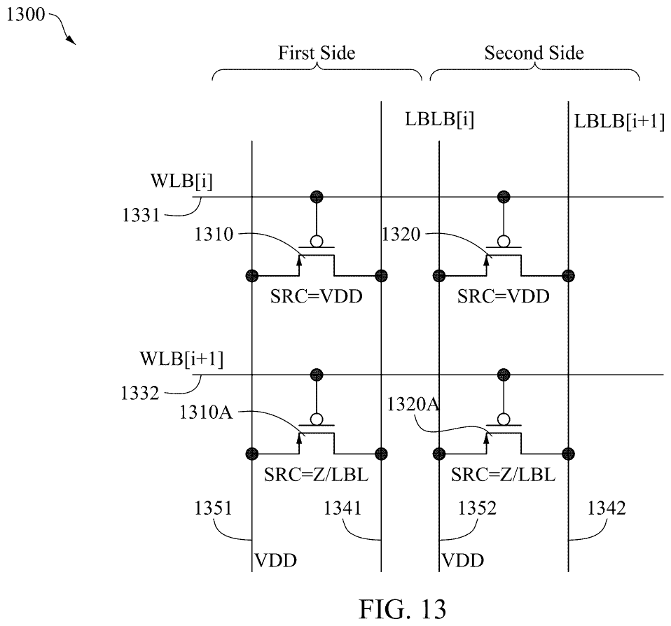

In some embodiments, the first bit line transistor 1271 and the second bit line transistor 1272 may have a common conductive type. For example, each of the first bit line transistor 1271 and the second bit line transistor 1272 may have an N-type, as shown. In some embodiments, the first bit line transistor 1271 and the second bit line transistor 1272 may have respectively different conductive types. The configuration and arrangement (e.g., of the global bit line 1261, the first bit line 1241, the second bit line 1242, etc.) discussed herein are non-limiting examples and can be implemented as any of various other configurations while remaining within the scope of the present disclosure. In some embodiments, although not shown in FIG. 13, the memory circuit 1300 may include a plurality of global bit lines (e.g., global bit line 1261), to which one or more bit lines (e.g., the first bit line 1241, the second bit line 1242, etc.) can be connected. In some embodiments, each of the bit lines (e.g., the first bit line 1241, the second bit line 1242, etc.) can be connected to the global bit line 1261 through a different transistor or logic component, such that each of the bit lines can be controlled for a certain function.

FIG. 13 illustrates a circuit diagram of an example memory circuit (or an example memory device) 1300, in accordance with some embodiments. In some embodiments, the memory circuit 1300 may be substantially similar to or incorporate features of the memory circuit 100, the memory circuit 200, etc. For example, the memory circuit 1300 includes a first transistor 1310, another first transistor 1310A, a second transistor 1320, another second transistor 1320A, a first word line 1331, a second word line 1332, a first bit line 1341, a second bit line 1342, a first conductive rail 1351, a second conductive rail 1352, etc. It should be appreciated that the memory circuit 1300 of FIG. 13 is simplified for illustrative purposes, and thus, can be implemented as any of various other configurations while remaining within the scope of the present disclosure.

In some embodiments, respective gate terminals of a plurality of stacked transistors of the memory circuit 1300 may be connected to a corresponding one of the word lines (e.g., the first word line 1331, the second word line 1332, etc.). For example, as shown, the first word line 1331 may be commonly connected to respective gate terminals of the first transistor 1310 and the second transistor 1320. That is, the first word line 1331 may be shared by the stacked transistors (e.g., the first transistor 1310 and the second transistor 1320). Although two stacked transistors (e.g., the first transistor 1310 and the second transistor 1320) are shown, the memory circuit 1300 may include any number of transistors that are vertically stacked on top of each other. For example, the memory circuit 1300 may include N transistors (e.g., N PMOS cells; wherein N=1, 2, 3, 4, 5, etc.), which can improve the bit density by a factor of N.

The N transistors may have different varieties of conductive types. For example, at least two of the N transistors (e.g., the first transistor 1310 and the second transistor 1320) may have a common conductive type, for example, P-type as shown in FIG. 13. In some embodiments, at least two of the N transistors may have respectively different conductive types (not shown in FIG. 13).

In some embodiments, the first bit line 1341 may be connected to a first source/drain terminal of the first transistor 1310. The second bit line 1342 may be connected to a first source/drain terminal of the second transistor 1320. In some embodiments, the first bit line 1341 may be the i-th local bit line (LBL[i]). The second bit line 1342 may be the i+1-th local bit line (LBL[i+1]). As shown in FIG. 13, in some embodiments, the first bit line 1341 may be commonly connected to respective first source/drain terminals of a plurality of first transistors (e.g., including the first transistor 1310 and the other first transistor 1310A) of the memory cells. The second bit line 1342 may be commonly connected to respective first source/drain terminals of a plurality of second transistors (e.g., including the second transistor 1320 and the other second transistor 1320A) of the memory cells.

In some embodiments, respective second source/drain terminals of the first and second transistors of each of the memory cells may be configured as being one of: (i) connected to a first supply voltage (e.g., VDD) and connected to a second supply voltage (e.g., VSS), respectively, (ii) connected to the first supply voltage and floating, (iii) floating and connected to the second supply voltage, or (iv) both floating. For example, as shown, a second source/drain terminal of the first transistor 1310 and a second source/drain terminal of the second transistor 1320 can be connected to the first conductive rail 1351 (e.g., a first power rail carrying the first supply voltage, VDD) and the second conductive rail 1352 (e.g., a second power rail carrying the first supply voltage, VDD), respectively. As shown in FIG. 13, a second source/drain terminal of the other first transistor 1310A and a second source/drain terminal of the other second transistor 1320A can be both floating. Although not shown, in some embodiments, the second source/drain terminal of the first transistor 1310 and the second source/drain terminal of the second transistor 1320 can be (ii) connected to the first power rail carrying the first supply voltage and floating, or (iii) floating and connected to the second power rail carrying the second supply voltage. The configuration and arrangement (e.g., of the first transistor 1310, the second transistor 1320, etc.) discussed herein are non-limiting examples and can be implemented as any of various other configurations while remaining within the scope of the present disclosure. For example, although not shown in FIG. 13, the memory circuit 1300 may include a memory cell including stacked transistors (e.g., the first transistor 1310 and the second transistor 1320), while including another memory cell including one or more non-stacked transistors.

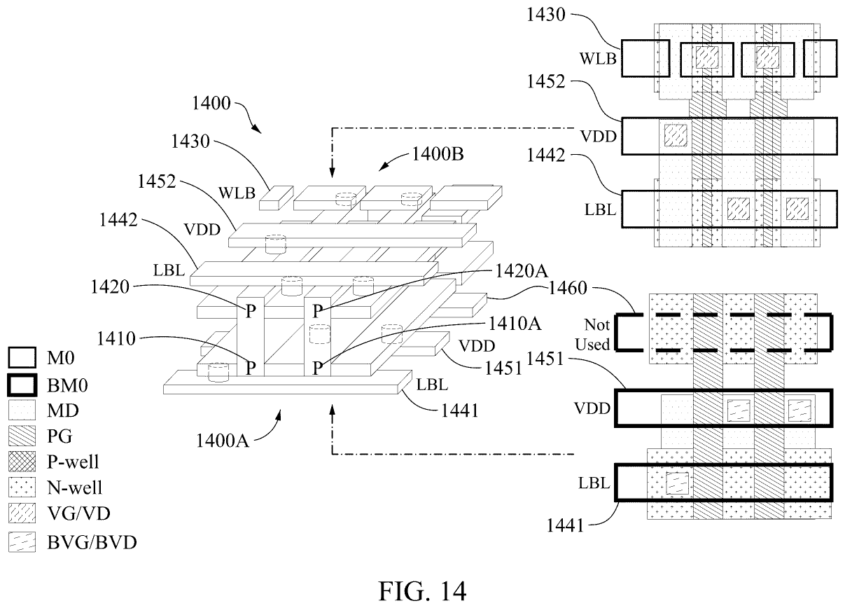

FIG. 14 illustrates an example layout 1400 configured to form a memory circuit, in accordance with some embodiments. In some embodiments, the layout 1400 may be configured to form the memory circuit 1300, etc. In FIG. 14, top views of a first side 1400A (e.g., a bottom) and a second side 1400B (e.g., a top) of the layout 1400 are shown. It should be appreciated that the layout 1400 of FIG. 14 is simplified for illustrative purposes, and thus, can be implemented as any of various other configurations while remaining within the scope of the present disclosure.

The layout 1400 is shown to include a first transistor 1410, another first transistor 1410A, a second transistor 1420, another second transistor 1420A, a first metal track 1441, a second metal track 1451, a third metal track 1442, a fourth metal track 1452, and a fifth metal track 1430. These components of the layout 1400 may be associated with the first transistor 1310, the other first transistor 1310A, the second transistor 1320, the other second transistor 1320A, the first word line 1331, the first bit line 1341, the first conductive rail 1351, the second bit line 1342, the second conductive rail 1352, and the word line (e.g., the first word line 1331, the second word line 1332, etc.), respectively, shown in FIG. 13.

In some embodiments, the first bit line (e.g., the first bit line 1341 of FIG. 13) and the first power rail (e.g., the first conductive rail 1351 of FIG. 13) may be formed as the first metal track 1441 and the second metal track 1451, respectively. In some embodiments, the second bit line (e.g., the second bit line 1342 of FIG. 13), the second power rail (e.g., the second conductive rail 1352 of FIG. 13), and the word line (e.g., the first word line 1331, the second word line 1332, etc. of FIG. 13) may be formed as the third metal track 1442, the fourth metal track 1452, and the fifth metal track 1430, respectively. In some embodiments, the first metal track 1441 and the second metal track 1451 may be formed below the stacked transistors (e.g., the first transistor 1410 and the second transistor 1420, etc.), while the third metal track 1442, the fourth metal track 1452, and the fifth metal track 1430 may be formed above the stacked transistors (e.g., the first transistor 1410 and the second transistor 1420, etc.). For example, as shown in FIG. 14, the first metal track 1441 and the second metal track 1451 may be formed on a first metallization layer BM0, which may be located below the stacked transistors. The third metal track 1442, the fourth metal track 1452, and the fifth metal track 1430 may be formed on a second metallization layer MO, which may be located above the stacked transistors.

In some embodiments, the first transistor 1410 and the second transistor 1420 may have a common conductive type. For example, each of the first transistor 1410 and the second transistor 1420 may have a P-type, as shown. In some embodiments, the first transistor 1410 and the second transistor 1420 may have respectively different conductive types (e.g., as shown in FIGS. 2 and 3).

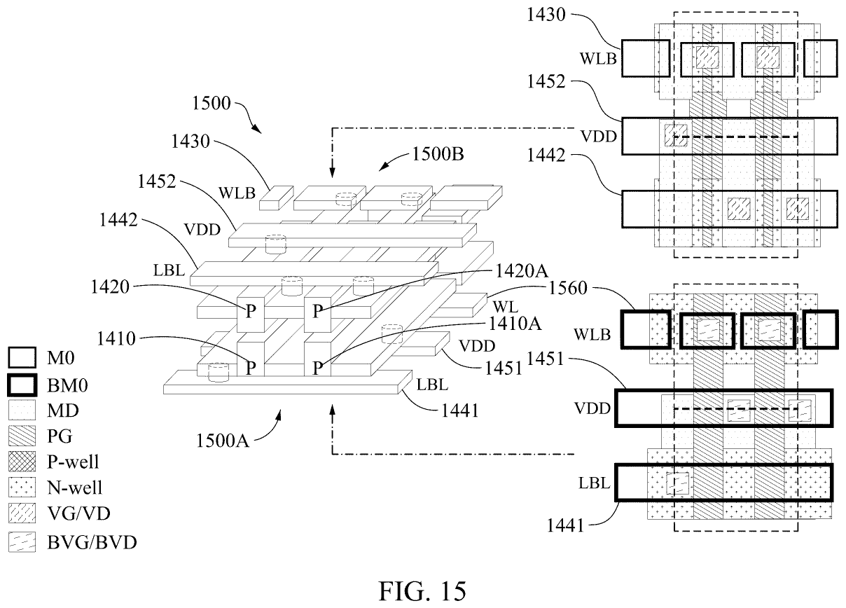

In some embodiments, the first metallization layer BM0 may include a portion 1460 that is not used (“Not Used”). For example, the portion 1460 may be a metal track that is not connected to the stacked transistors. The portion 1460, as discussed below and shown in FIG. 15, may be configured as a portion of a word line.

FIG. 15 illustrates an example layout 1500 configured to form a memory circuit, in accordance with some embodiments. In some embodiments, the layout 1500 may be configured to form the memory circuit 1300, etc. In FIG. 15, top views of a first side 1500A (e.g., a bottom) and a second side 1500B (e.g., a top) of the layout 1500 are shown. It should be appreciated that the layout 1500 of FIG. 15 is simplified for illustrative purposes, and thus, can be implemented as any of various other configurations while remaining within the scope of the present disclosure.

In some embodiments, the layout 1500 may be substantially similar to or incorporate features of the layout 1400 of FIG. 14. For example, the layout 1500 may be the layout 1400 that alternatively includes a sixth metal track 1560, as opposed to the portion 1460. In some embodiments, the layout 1500 may include the first transistor 1410 and the second transistor 1420 that are vertically arranged (e.g., as shown in FIG. 15) without being in contact with each other.

In some embodiments, a portion of the word line may be formed as the sixth metal track 1560. For example, the portions of the first word line (e.g., the first word line 931, the second word line 932, etc.) that are associated with the first transistor 1410 and the other first transistor 1410A may be formed as the sixth metal track 1560. In some embodiments, the sixth metal track 1560 may be formed below the stacked transistors (e.g., the first transistor 1410, the second transistor 1420, etc.).

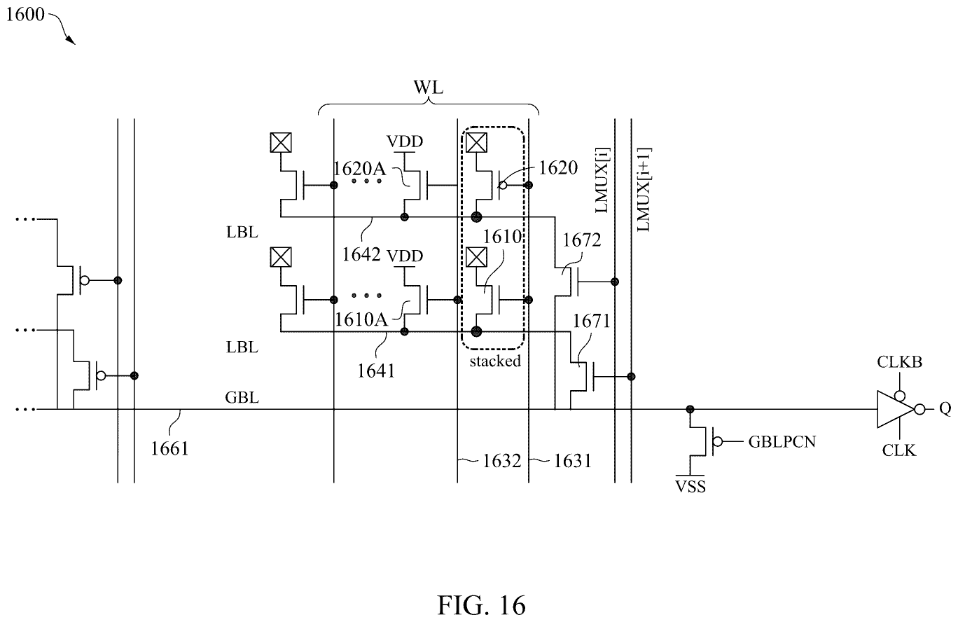

FIG. 16 illustrates a circuit diagram of an example memory circuit (or an example memory device) 1600, in accordance with some embodiments. In some embodiments, the memory circuit 1600 may be substantially similar to or incorporate features of the memory circuit 100, the memory circuit 200, the memory circuit 1300, etc. For example, the memory circuit 1600 includes a first transistor 1610, another first transistor 1610A, a second transistor 1620, another second transistor 1620A, a first word line 1631, a second word line 1632, a first bit line 1641, and a second bit line 1642, etc. The memory circuit 1600 may include a global bit line 1661, a first bit line transistor 1671, and a second bit line transistor 1672 additionally, as opposed to the memory circuit 1300. It should be appreciated that the memory circuit 1600 of FIG. 16 is simplified for illustrative purposes, and thus, can be implemented as any of various other configurations while remaining within the scope of the present disclosure.

In some embodiments, respective gate terminals of a plurality of stacked transistors of the memory circuit 1600 may be connected to a corresponding one of the word lines (e.g., the first word line 1631, the second word line 1632, etc.). For example, as shown, the first word line 1631 may be commonly connected to respective gate terminals of the first transistor 1610 and the second transistor 1620. In some embodiments, the first bit line 1641 may be connected to a first source/drain terminal of the first transistor 1610. The second bit line 1642 may be connected to a first source/drain terminal of the second transistor 1620. In some embodiments, the first bit line 1641 may be a first local bit line (LBL). The second bit line 1642 may be a second local bit line (LBL). As shown in FIG. 16, in some embodiments, the first bit line 1641 may be commonly connected to respective first source/drain terminals of a plurality of first transistors (e.g., including the first transistor 1610 and the other first transistor 1610A) of the memory cells. The second bit line 1642 may be commonly connected to respective first source/drain terminals of a plurality of second transistors (e.g., including the second transistor 1620 and the other second transistor 1620A) of the memory cells.

In some embodiments, the global bit line 1661 may be connected to the first bit line 1641 and the second bit line 1642. In some embodiments, the global bit line 1661 may be connected to the first bit line 1641 through the first bit line transistor 1671, and connected to the second bit line 1642 through the second bit line transistor 1672. As shown in FIG. 16, a first source/drain terminal of the first bit line transistor 1671 may be connected to the first bit line 1641, and a second source/drain terminal of the first bit line transistor 1671 may be connected to the global bit line 1661. A gate terminal of the first bit line transistor 1671 can be connected to an i-th line assertion signal LMUX[i]. A first source/drain terminal of the second bit line transistor 1672 may be connected to the second bit line 1642, and a second source/drain terminal of the second bit line transistor 1672 may be connected to the global bit line 1661. A gate terminal of the second bit line transistor 1672 can be connected to an i+1-th line assertion signal LMUX[i+1].

In some embodiments, the first bit line transistor 1671 and the second bit line transistor 1672 may have a common conductive type. For example, each of the first bit line transistor 1671 and the second bit line transistor 1672 may have a P-type, as shown. In some embodiments, the first bit line transistor 1671 and the second bit line transistor 1672 may have respectively different conductive types. The configuration and arrangement (e.g., of the global bit line 1661, the first bit line 1641, the second bit line 1642, etc.) discussed herein are non-limiting examples and can be implemented as any of various other configurations while remaining within the scope of the present disclosure. In some embodiments, although not shown in FIG. 16, the memory circuit 1600 may include a plurality of global bit lines (e.g., global bit line 1661), to which one or more bit lines (e.g., the first bit line 1641, the second bit line 1642, etc.) can be connected. In some embodiments, each of the bit lines (e.g., the first bit line 1641, the second bit line 1642, etc.) can be connected to the global bit line 1661 through a different transistor or logic component, such that each of the bit lines can be controlled for a certain function.

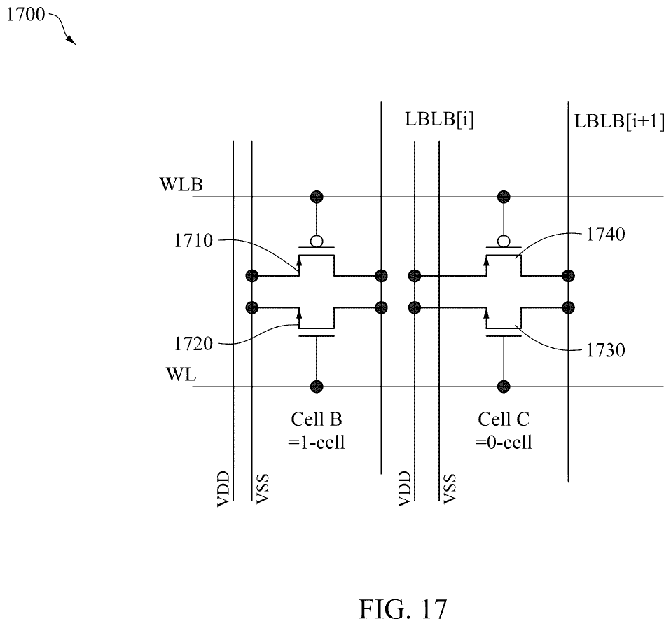

FIG. 17 illustrates a circuit diagram of an example memory circuit (or an example memory device) 1700, in accordance with some embodiments. The memory circuit 1700 includes a first transistor 1710, a second transistor 1720, a third transistor 1730, and a fourth transistor 1740, etc. It should be appreciated that the memory circuit 1700 of FIG. 17 is simplified for illustrative purposes, and thus, can be implemented as any of various other configurations while remaining within the scope of the present disclosure.

With the memory circuit 1700, the second transistor 1720 and the third transistor 1730 can be reused without using the first transistor 1710 or the fourth transistor 1740. In some embodiments, a bit line voltage after a read operation may not depend on a pre-charge level of the bit line voltage (e.g., whether the bit line voltage is high or low). For example, with the pre-charge of “high” and the word line (e.g., WL, WLB in FIG. 17) of “high,” the first transistor 1710, the second transistor 1720, the third transistor 1730, and the fourth transistor 1740 may be “off,” “on,” “off,” and “on,” respectively. With the pre-charge of “low” and the word line (e.g., WL, WLB in FIG. 17) of “low,” the first transistor 1710, the second transistor 1720, the third transistor 1730, and the fourth transistor 1740 may be “off,” “off,” “on,” and “on,” respectively. With the local bit line (LBL) of “high” and the word lines WL, WLB of “high,” the first transistor 1710, the second transistor 1720, the third transistor 1730, and the fourth transistor 1740 may be “off,” “on,” “on,” and “off,” respectively. In some examples, when the LBL is charged/discharged by read operation, the first transistor 1710, the second transistor 1720, the third transistor 1730, and the fourth transistor 1740 may be “off,” “on,” “off,” and “off,” respectively. With the local bit line (LBL) of “low” and the word lines WL, WLB of “low,” the first transistor 1710, the second transistor 1720, the third transistor 1730, and the fourth transistor 1740 may be “on,” “off,” “off,” and “on,” respectively. In some examples, when the LBL is charged/discharged by read operation, the first transistor 1710, the second transistor 1720, the third transistor 1730, and the fourth transistor 1740 may be “off,” “off,” “off,” and “on,” respectively. In some embodiments, the memory circuit 1700 can be configured such that “0” can be read with a global bit line of “high” while “1” can be read with the global bit line of “low.”

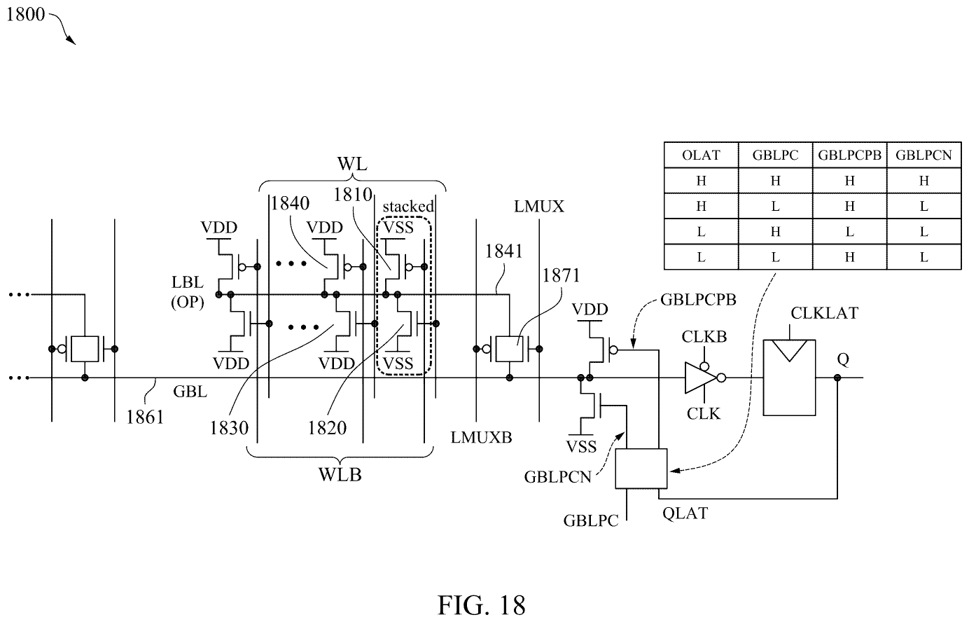

FIG. 18 illustrates a circuit diagram of an example memory circuit (or an example memory device) 1800, in accordance with some embodiments. In some embodiments, the memory circuit 1800 may be substantially similar to or incorporate features of the memory circuit 100, the memory circuit 1700, etc. For example, the memory circuit 1800 includes a first transistor 1810, a second transistor 1820, a third transistor 1830, a fourth transistor 1840, a bit line 1841, a global bit line 1861, one or more bit line transistors 1871, etc. It should be appreciated that the memory circuit 1800 of FIG. 18 is simplified for illustrative purposes, and thus, can be implemented as any of various other configurations while remaining within the scope of the present disclosure.

The first transistor 1810 and the second transistor 1820 may be vertically stacked on top of each other. In some embodiments, the first transistor 1810 and the second transistor 1820 may have a common conductive type. For example, each of the first transistor 1810 and the second transistor 1820 may have an N-type or a P-type. In some embodiments, the first transistor 1810 and the second transistor 1820 may have respectively different conductive types. For example, as shown, the first transistor 1810 may have a P-type, and the second transistor 1820 may have an N-type, or vice versa.

In some embodiments, respective gate terminals of a plurality of stacked transistors of the memory circuit 1800 may be connected to a corresponding one of the word lines. In some embodiments, the bit line 1841 may be connected to first source/drain terminals of the first transistor 1810, the second transistor 1820, the third transistor 1830, and the fourth transistor 1840. In some embodiments, the bit line 1841 may be a local bit line (LBL). In some embodiments, the global bit line 1861 may be connected to the bit line 1841. In some embodiments, the global bit line 1861 may be connected to the bit line 1841 through the one or more bit line transistors 1871. Gate terminals of the one or more bit line transistors 1871 can be connected to line assertion signals LMUX and/or LMUXB. In some embodiments, the one or more bit line transistors 1871 may include a pair of a P-type transistor and an N-type transistor.

In some embodiments, a pre-charge level (e.g., “high” or “low”) can be determined based on a former Q state. For example, the memory circuit 1800 can be configured to provide the former Q state as shown in FIG. 18. In some embodiments, the former Q state can be stored in the CLKLAT, based on the GBLPCPB, GBLPCN, GBLPC, etc.

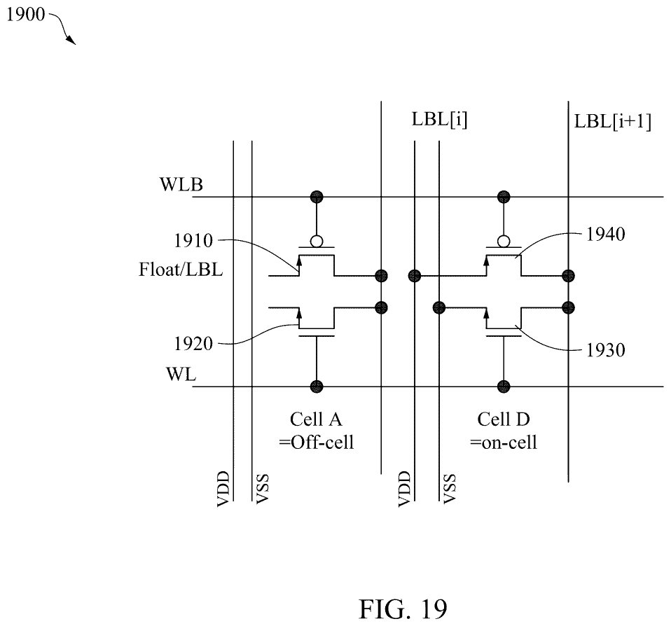

FIG. 19 illustrates a circuit diagram of an example memory circuit (or an example memory device) 1900, in accordance with some embodiments. The memory circuit 1900 includes a first transistor 1910, a second transistor 1920, a third transistor 1930, and a fourth transistor 1940, etc. It should be appreciated that the memory circuit 1900 of FIG. 19 is simplified for illustrative purposes, and thus, can be implemented as any of various other configurations while remaining within the scope of the present disclosure.

With the memory circuit 1900, the first transistor 1910 and the fourth transistor 1940 can be reused without using the second transistor 1920 or the third transistor 1930. In some embodiments, a bit line voltage after a read operation may not depend on a pre-charge level of the bit line voltage (e.g., whether the bit line voltage is high or low). For example, with the pre-charge of “high” and the word line (e.g., WL, WLB in FIG. 19) of “high,” the first transistor 1910, the second transistor 1920, the third transistor 1930, and the fourth transistor 1940 may be “off,” “on,” “off,” and “on,” respectively. With the pre-charge of “low” and the word line (e.g., WL, WLB in FIG. 19) of “low,” the first transistor 1910, the second transistor 1920, the third transistor 1930, and the fourth transistor 1940 may be “off,” “off,” “on,” and “on,” respectively. In some embodiments, the memory circuit 1900 can be configured such that “0” can be read with a bit line being stable while “1” can be read with the bit line toggled.

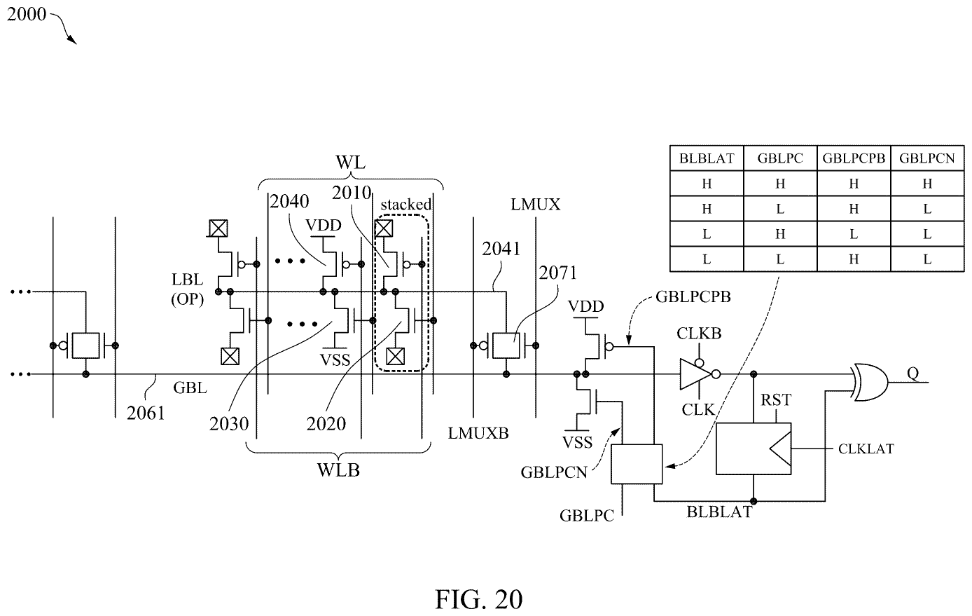

FIG. 20 illustrates a circuit diagram of an example memory circuit (or an example memory device) 2000, in accordance with some embodiments. In some embodiments, the memory circuit 2000 may be substantially similar to or incorporate features of the memory circuit 100, the memory circuit 1900, etc. For example, the memory circuit 2000 includes a first transistor 2010, a second transistor 2020, a third transistor 2030, a fourth transistor 2040, a bit line 2041, a global bit line 2061, one or more bit line transistors 2071, etc. It should be appreciated that the memory circuit 2000 of FIG. 20 is simplified for illustrative purposes, and thus, can be implemented as any of various other configurations while remaining within the scope of the present disclosure.

In some embodiments, a pre-charge level (e.g., “high” or “low”) can be determined based on a former voltage of the global bit line 2061. For example, the memory circuit 2000 can be configured to provide the former voltage of the global bit line 2061 as shown in FIG. 20. In some embodiments, the former voltage of the global bit line 2061 can be stored in the CLKLAT, based on the BLBLAT, GBLPC, GBLPCPB, GBLPCN, etc.

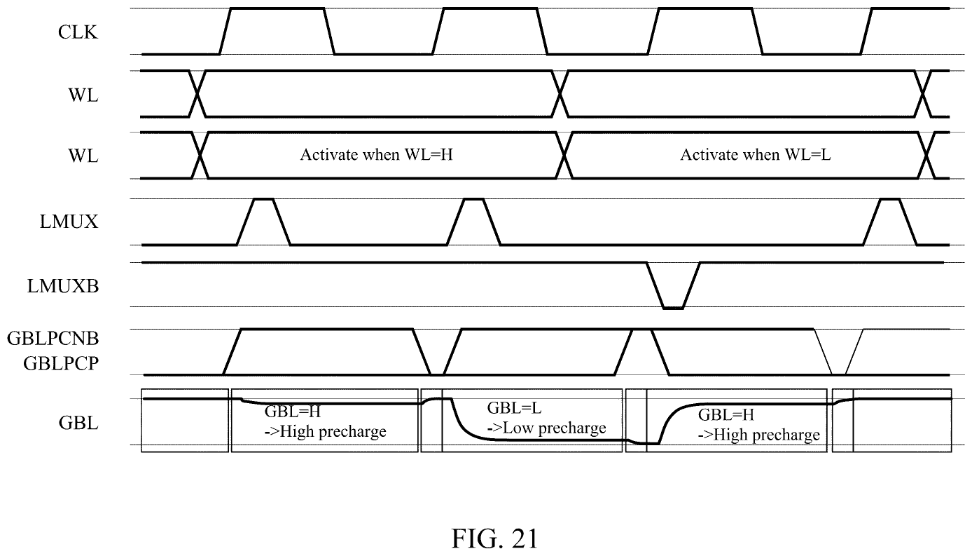

FIG. 21 illustrates example waveforms of various signals associated with a memory circuit (or an example memory device), in accordance with some embodiments. For example, the waveforms of FIG. 21 may be associated with the memory circuit 1800, the memory circuit 2000, etc. In FIG. 21, a clock signal (CLK), a word line assertion signal WL, a line assertion signal LMUX, a line assertion signal LMUXB, a global pre-charge signal GBLPCNB, a global pre-charge signal GBLPCP, a global bit line signal GBL, etc. are shown. It should be appreciated that the waveforms of FIG. 21 are simplified for illustrative purposes.

In some embodiments, a pre-charge level of the global bit line signal GBL may be based on a previous read-out result. For example, the pre-charge level of the global bit line signal GBL may be “VDD” or “VSS” based on the previous read-out result (e.g., the former Q state, the former voltage of the global bit line, etc.). As shown in FIG. 21, the pre-charge level of the global bit line signal GBL may be “High” when the global bit line signal GBL is at “High” during the previous read-out, while the pre-charge level of the global bit line signal GBL may be “Low” when the global bit line signal GBL is at “Low” during the previous read-out.

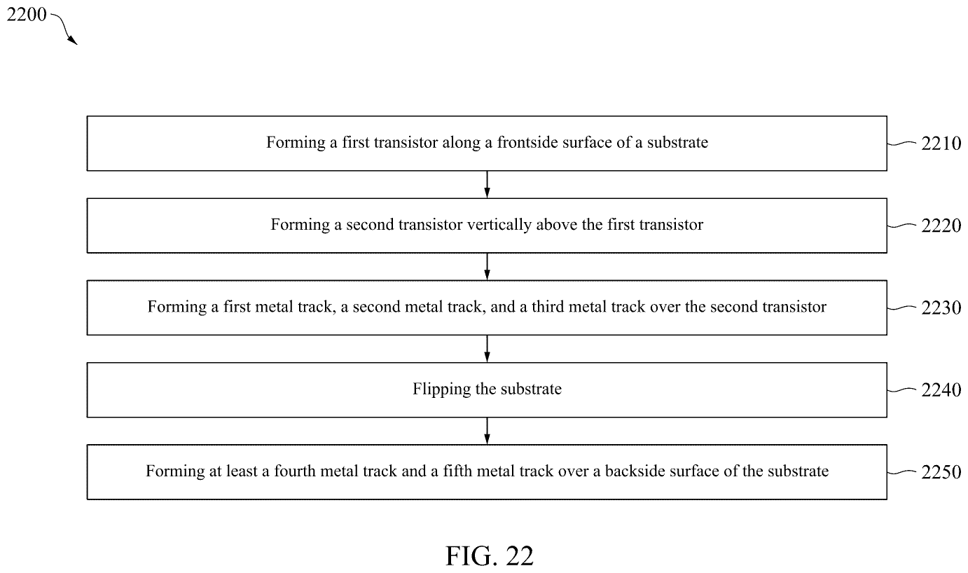

FIG. 22 illustrates a flow chart of an example method 2200 for forming a memory circuit, in accordance with some embodiments. In some embodiments, the method 2200 can be performed to form a memory circuit (e.g., the memory circuit 100, etc.), and thus, some of the references used above may be reused in the following discussion of the method 2200. It is noted that the method 2200 is merely an example and is not intended to limit the present disclosure. Accordingly, it is understood that additional operations may be provided before, during, and after the method 2200 of FIG. 22, and that some other operations may only be briefly described herein.

In a brief overview, the method 2200 may begin with operation 2210 of forming a first transistor along a frontside (e.g., the second side 300B) surface of a substrate. The method 2200 may continue to operation 2220 of forming a second transistor vertically above the first transistor. The method 2200 may continue to operation 2230 of forming a first metal track, a second metal track, and a third metal track over the second transistor. The method 2200 may continue to operation 2240 of flipping the substrate. The method 2200 may continue to operation 2250 of forming at least a fourth metal track and a fifth metal track over a backside surface of the substrate.

At operation 2210, a first transistor (e.g., the first transistor 210) can be formed along a frontside surface of a substrate. At operation 2220, a second transistor (e.g., the second transistor 220) can be formed vertically above the first transistor.

At operation 2230, a first metal track (e.g., the third metal track 342), a second metal track (e.g., the fourth metal track 352), and a third metal track (e.g., the fifth metal track 330) can be formed over the second transistor. The first metal track, the second metal track, and the third metal track may be operatively configured as a first bit line (e.g., the second bit line 242) connected to a first source/drain terminal of the second transistor, a first power rail (e.g., the second conductive rail 252) carrying a first supply voltage, and a word line (e.g., the word line 230) connected to gate terminals of both the first and second transistors, respectively. At operation 2240, the substrate can be flipped.

At operation 2240, at least a fourth metal track (e.g., the first metal track 341) and a fifth metal track (e.g., the second metal track 351) can be formed over a backside (e.g., the first side 300A) surface of the substrate. The fourth metal track and the fifth metal track may be operatively configured as a second bit line (e.g., the first bit line 241) connected to a first source/drain terminal of the first transistor and a second power rail (e.g., the first conductive rail 251) carrying a second supply voltage, respectively.

In some embodiments, the method 2200 may include forming a first bit line transistor (e.g., the first bit line transistor 571) connecting a global bit line (e.g., the global bit line 760) to the first bit line. The method 2200 may include forming a second bit line transistor (e.g., the second bit line transistor 572) connecting the global bit line to the second bit line. In some embodiments, the first bit line transistor and the second bit line transistor may have a common conductive type. For example, each of the first bit line transistor and the second bit line transistor may have an N-type or a P-type. In some embodiments, the first bit line transistor and the second bit line transistor may have respectively different conductive types. For example, the first bit line transistor may have a P-type, and the second bit line transistor may have an N-type, or vice versa.

In one aspect of the present disclosure, a memory device is disclosed. The memory device includes a plurality of memory cells, each of the plurality of memory cells including a first transistor and a second transistor that are vertically stacked on top of each other, a word line commonly connected to respective gate terminals of the first transistor and the second transistor, a first bit line connected to a first source/drain terminal of the first transistor, and a second bit line connected to a first source/drain terminal of the second transistor. A second source/drain terminal of the first transistor and a second source/drain terminal of the second transistor are configured as being one of: (i) connected to a first power rail carrying a first supply voltage and connected to a second power rail carrying a second supply voltage, respectively, (ii) connected to the first power rail and floating, (iii) floating and connected to the second power rail, or (iv) both floating.

In another aspect of the present disclosure, a memory circuit is disclosed. The memory circuit includes a memory array including a plurality of memory cells, each of the plurality of memory cells including a first transistor and a second transistor, a plurality of word lines, wherein respective gate terminals of the first and second transistors of each of the memory cells are connected to a corresponding one of the word lines, a first bit line commonly connected to respective first source/drain terminals of the first transistors of the memory cells, and a second bit line commonly connected to respective first source/drain terminals of the second transistors of the memory cells. Respective second source/drain terminals of the first and second transistors of each of the memory cells are configured as being one of: (i) connected to a first supply voltage and connected to a second supply voltage, respectively, (ii) connected to the first supply voltage and floating, (iii) floating and connected to the second supply voltage, or (iv) both floating.

In yet another aspect of the present disclosure, a method is disclosed. The method includes forming a first transistor along a frontside surface of a substrate, forming a second transistor vertically above the first transistor, forming a first metal track, a second metal track, and a third metal track over the second transistor, wherein the first metal track, the second metal track, and the third metal track are operatively configured as a first bit line connected to a first source/drain terminal of the second transistor, a first power rail carrying a first supply voltage, and a word line connected to gate terminals of both the first and second transistors, respectively, flipping the substrate, and forming at least a fourth metal track and a fifth metal track over a backside surface of the substrate, wherein the fourth metal track and the fifth metal track are operatively configured as a second bit line connected to a first source/drain terminal of the first transistor and a second power rail carrying a second supply voltage, respectively.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a plurality of memory cells, each of the plurality of memory cells comprising a first transistor and a second transistor that are vertically stacked on top of each other;
a word line commonly connected to respective gate terminals of the first transistor and the second transistor;
a first bit line connected to a first source/drain terminal of the first transistor; and
a second bit line connected to a first source/drain terminal of the second transistor;
wherein a second source/drain terminal of the first transistor and a second source/drain terminal of the second transistor are configured as being one of: (i) connected to a first power rail carrying a first supply voltage and connected to a second power rail carrying a second supply voltage, respectively; (ii) connected to the first power rail and floating; (iii) floating and connected to the second power rail; or (iv) both floating.

2. The memory device of claim 1, wherein each of the memory cells is operatively configured as a read-only-memory (ROM) cell.

3. The memory device of claim 1, wherein the first transistor and the second transistor have a common conductive type.

4. The memory device of claim 1, wherein the first transistor and the second transistor have respectively different conductive types.

5. The memory device of claim 1, wherein the first bit line and the first power rail are formed as a first metal track and a second metal track, respectively, and the second bit line, the second power rail, and the word line are formed as a third metal track, a fourth metal track, and a fifth metal track, respectively.

6. The memory device of claim 5, wherein the first and second metal tracks are formed below the stacked first and second transistors, and the third to fifth metal tracks are formed above the stacked first and second transistors.

7. The memory device of claim 1, wherein the first bit line, the first power rail, and a portion of the word line are formed as a first metal track, a second metal track, and a third metal track, respectively, and the second bit line, the second power rail, and another portion of the word line are formed as a fourth metal track, a fifth metal track, and a sixth metal track, respectively.

8. The memory device of claim 6, wherein the first to third metal track are formed below the stacked first and second transistors, and the fourth to sixth metal tracks are formed above the stacked first and second transistors.

9. A memory circuit, comprising:
a memory array comprising a plurality of memory cells, each of the plurality of memory cells comprising a first transistor and a second transistor;
a plurality of word lines, wherein respective gate terminals of the first and second transistors of each of the memory cells are connected to a corresponding one of the word lines;
a first bit line commonly connected to respective first source/drain terminals of the first transistors of the memory cells; and
a second bit line commonly connected to respective first source/drain terminals of the second transistors of the memory cells;
wherein respective second source/drain terminals of the first and second transistors of each of the memory cells are configured as being one of: (i) connected to a first supply voltage and connected to a second supply voltage, respectively; (ii) connected to the first supply voltage and floating; (iii) floating and connected to the second supply voltage; or (iv) both floating.

10. The memory circuit of claim 9, further comprising:
a first global bit line connected to the first bit line through a first bit line transistor; and
a second global bit line connected to the second bit line through a second bit line transistor.

11. The memory circuit of claim 9, further comprising:
a global bit line connected to the first bit line through a first bit line transistor and connected to the second bit line through a second bit line transistor.

12. The memory circuit of claim 9, wherein each of the memory cells is operatively configured as a read-only-memory (ROM) cell.

13. The memory circuit of claim 9, wherein the first transistor and the second transistor have a common conductive type.

14. The memory circuit of claim 9, wherein the first transistor and the second transistor have respectively different conductive types.

15. The memory circuit of claim 9, wherein the first bit line and a first power rail carrying the first supply voltage are formed as a first metal track and a second metal track, respectively, and the second bit line, a second power rail carrying the second supply voltage, and the word line are formed as a third metal track, a fourth metal track, and a fifth metal track, respectively.

16. The memory circuit of claim 15,
wherein the first transistor and the second transistor are vertically stacked on top of each other, and
wherein the first and second metal track are formed below the stacked first and second transistors, and the third to fifth metal tracks are formed above the stacked first and second transistors.

17. The memory circuit of claim 9, wherein the first bit line, a first power rail carrying the first supply voltage, and a portion of the word line are formed as a first metal track, a second metal track, and a third metal track, respectively, and the second bit line, a second power rail carrying the second supply voltage, and another portion of the word line are formed as a fourth metal track, a fifth metal track, and a sixth metal track, respectively.

18. The memory circuit of claim 16, wherein the first to third metal track are formed below the stacked first and second transistors, and the fourth to sixth metal tracks are formed above the stacked first and second transistors.

19. A method for forming a memory device, comprising:
forming a first transistor along a frontside surface of a substrate;
forming a second transistor vertically above the first transistor;
forming a first metal track, a second metal track, and a third metal track over the second transistor, wherein the first metal track, the second metal track, and the third metal track are operatively configured as a first bit line connected to a first source/drain terminal of the second transistor, a first power rail carrying a first supply voltage, and a word line connected to gate terminals of both the first and second transistors, respectively;
flipping the substrate; and
forming at least a fourth metal track and a fifth metal track over a backside surface of the substrate, wherein the fourth metal track and the fifth metal track are operatively configured as a second bit line connected to a first source/drain terminal of the first transistor and a second power rail carrying a second supply voltage, respectively.

20. The method of claim 19, further comprising:
forming a first bit line transistor connecting a global bit line to the first bit line; and
forming a second bit line transistor connecting the global bit line to the second bit line.
